(19) United States
(12) Patent Application Publication
(10) Pub. No.: US 2024/0387105 A1
(43) Pub. Date: Nov. 21, 2024

(54) ELECTRONIC COMPONENT AND MOUNTING STRUCTURE FOR ELECTRONIC COMPONENT

(71) Applicant: Murata Manufacturing Co., Ltd., Nagaokakyo-shi (JP)

(72) Inventors: Motonori TAKEDA, Nagaokakyo-shi (JP); Yoshiyuki ABE, Nagaokakyo-shi (JP)

(21) Appl. No.: 18/789,816

(22) Filed: Jul. 31, 2024

Related U.S. Application Data
(63) Continuation of application No. PCT/JP2023/025663, filed on Jul. 12, 2023.

(30) Foreign Application Priority Data
Oct. 28, 2022 (JP) 2022-173005

(51) Int. Cl. H01G 2/06; H01G 4/008; H01G 4/012; H01G 4/12; H01G 4/232; H01G 4/30

(52) U.S. Cl. CPC H01G 2/065; H01G 4/008; H01G 4/012; H01G 4/1227; H01G 4/232; H01G 4/30

(57) ABSTRACT

An electronic component includes a component body with a length in a length direction, and first and second external electrodes respectively provided at both ends of the component body in the length direction. The component body includes a central outer peripheral portion protruding outwardly beyond the first and second external electrodes in one direction orthogonal or substantially orthogonal to the length direction, in at least a portion of an area exposed between the pair of external electrodes.

### CROSS REFERENCE TO RELATED APPLICATIONS

This application claims the benefit of priority to Japanese Patent Application No. 2022-173005 filed on Oct. 28, 2022 and is a Continuation Application of PCT Application No. PCT/JP2023/025663 filed on Jul. 12, 2023. The entire contents of each application are hereby incorporated herein by reference.

### BACKGROUND OF THE INVENTION

### 1. Field of the Invention

The present invention relates to electronic components and mounting structures for electronic components.

### 2. Description of the Related Art

Conventionally, a multilayer ceramic capacitor is known as a two-terminal electronic component, in which a plurality of dielectric layers and a plurality of internal electrode layers are alternately stacked, and external electrodes are arranged at both ends of a rectangular parallelepiped body. Such a multilayer ceramic capacitor is mounted on a circuit-containing board by soldering the external electrodes to a pair of lands provided on the board (refer to Japanese Unexamined Patent Application, Publication No. 2014-86606, etc.). In general, as disclosed in Japanese Unexamined Patent Application, Publication No. 2014-86606, the external electrodes of multilayer ceramic capacitors protrude towards the board below the body. Therefore, the lands contact the external electrodes, and create a gap between the surface of the board and the body.

When mounting the conventional multilayer ceramic capacitor on the board as described above, it has been difficult for the solder to sufficiently penetrate between the lands and the external electrodes, and it has been challenging to ensure an adequate amount of solder between the lands and the external electrodes. If the amount of solder in this portion is insufficient, the board may bend, causing stress to concentrate at the edge of the portion of the external electrodes extending towards the body, potentially causing cracks in the body, and thus there has been room for improvement.

### SUMMARY OF THE INVENTION

Therefore, example embodiments of the present invention provide electronic components and mounting for structures electronic components that are each able to reduce or prevent cracks.

An electronic component according to an example embodiment of the present invention includes a component body with a length in a length direction, and a pair of external electrodes respectively at both ends of the component body in the length direction. The component body includes a protrusion protruding outward beyond the external electrodes in a direction orthogonal or substantially orthogonal to the length direction, in at least a portion of an area exposed between the pair of external electrodes.

In a mounting structure for an electronic component according to an example embodiment of the present invention, a pair of external electrodes of the electronic component are respectively connected to a pair of lands spaced apart on a surface of a board. The electronic component includes a component body and the pair of external electrodes on the component body. The component body is in contact with the board, and a gap is provided between each of the pair of external electrodes and the board.

Example embodiments of the present invention provide electronic components and mounting structures for electronic components each able to reduce or prevent cracks.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic perspective view of a multilayer ceramic capacitor according to an example embodiment of the present invention.

FIG. 2 is a view in the direction of the arrow II in FIG. 1.

FIG. 3 is a view in the direction of the arrow III in FIG. 1.

FIG. 4 is a cross-sectional view taken along the line IV-IV in FIG. 2.

FIG. 5 is a cross-sectional view taken along the line V-V in FIG. 3.

FIG. 6 is a schematic diagram illustrating an example of a method of manufacturing a multilayer ceramic capacitor according to an example embodiment of the present invention, presenting steps in sequential order from (a) to (d).

FIG. 7 is a plan view illustrating a mounting structure according to an example embodiment of the present invention.

FIG. 8 is a cross-sectional view taken along the line VIII-VIII in FIG. 7.

FIG. 9 is an enlarged view of the section IX in FIG. 8.

FIG. 10 is a diagram corresponding to FIG. 9, illustrating a conventional mounting structure.

FIG. 11 is a WT cross-sectional view corresponding to FIG. 5, illustrating a modification of a multilayer ceramic capacitor according to an example embodiment of the present invention.

### DETAILED DESCRIPTION OF THE EXAMPLE EMBODIMENTS

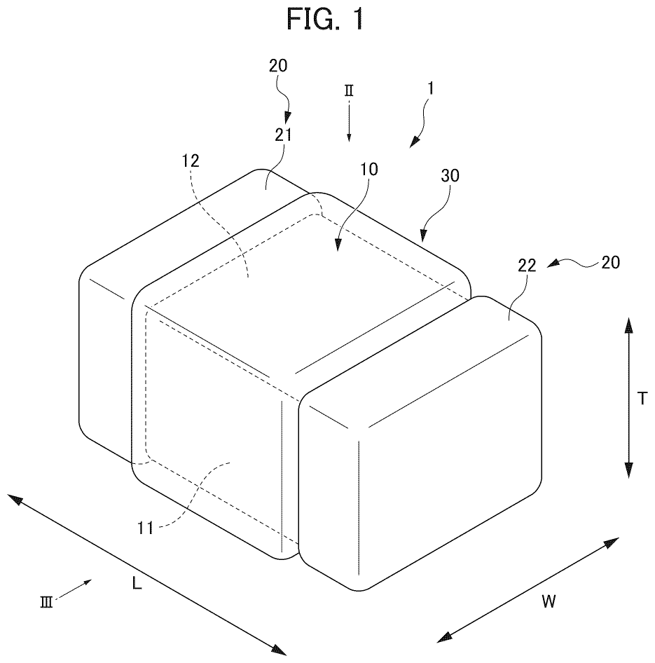

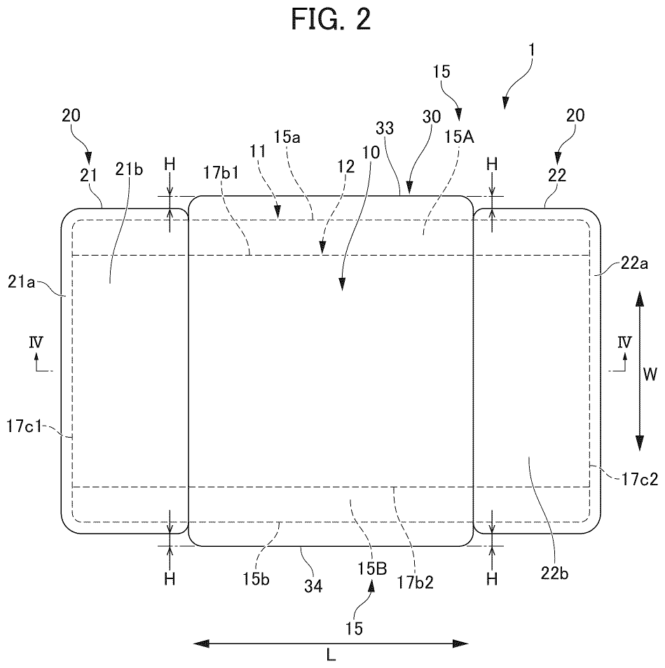

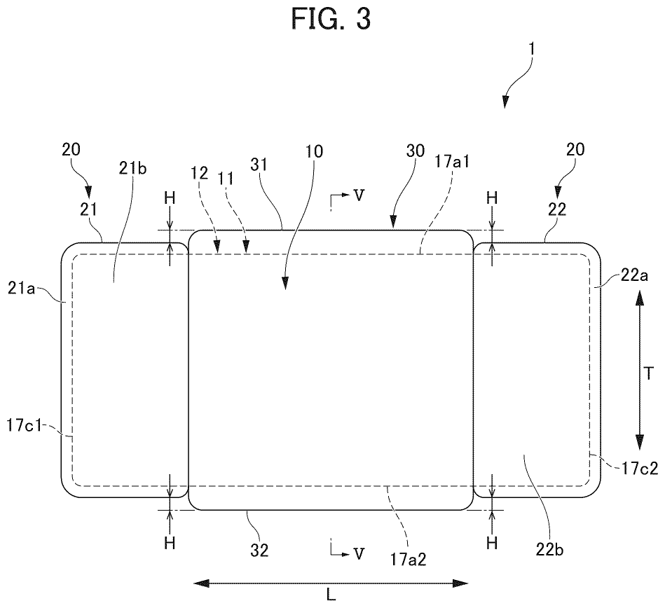

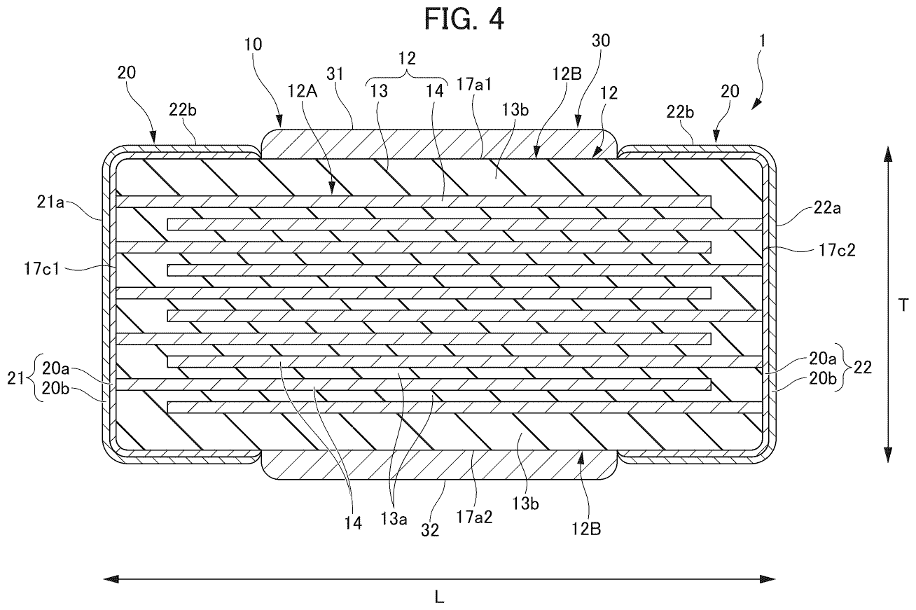

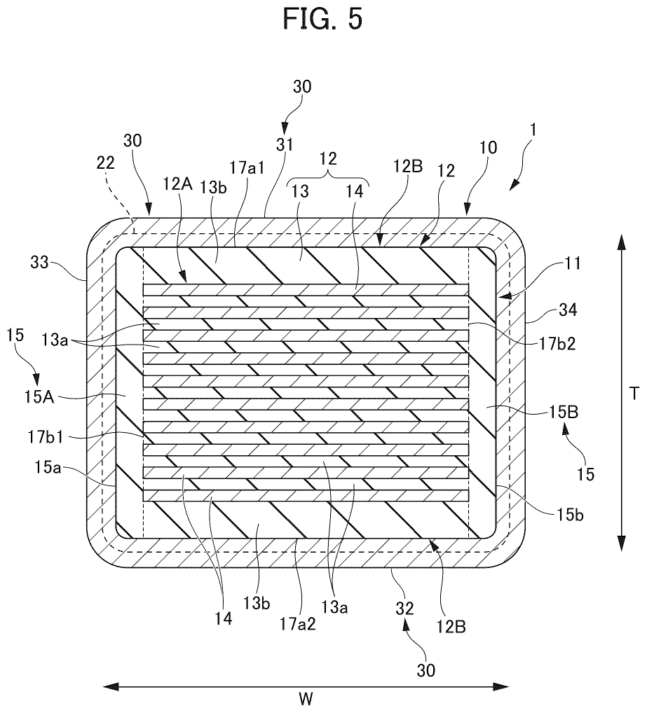

Hereinafter, example embodiments of the present invention will be described with reference to the drawings. FIG. 1 is a schematic perspective view of a multilayer ceramic capacitor 1 as an electronic component according to an example embodiment of the present invention. FIG. 2 is a view in the direction of the arrow II in FIG. 1. FIG. 3 is a view in the direction of the arrow III in FIG. 1. FIG. 4 is a cross-sectional view taken along the line IV-IV in FIG. 2. FIG. 5 is a cross-sectional view taken along the line V-V in FIG. 3.

As illustrated in FIG. 1, a multilayer ceramic capacitor 1 according to an example embodiment of a present invention as a whole has a rectangular or substantially rectangular parallelepiped shape. The multilayer ceramic capacitor 1 includes a component body 10 and a pair of external electrodes 20 spaced apart on the component body 10.

As illustrated in FIGS. 2 and 3, the component body 10 includes a base body 11 and a central outer peripheral portion 30 provided on the base body 11.

In FIGS. 1 to 3, the arrow L indicates the length direction of the multilayer ceramic capacitor 1 and the base body 11. In FIGS. 1 and 2, the arrow W indicates the width direction, which is orthogonal or substantially orthogonal to the length direction L, of the multilayer ceramic capacitor 1 and the base body 11. In FIGS. 1 and 3, the arrow T indicates the lamination direction, which is orthogonal or substantially orthogonal to both the length direction L and the width direction W, of the multilayer ceramic capacitor 1 and the base body 11. The lamination direction T corresponds to the thickness direction of the multilayer ceramic capacitor 1 and the base body 11. The cross-sectional view of FIG. 4 illustrates an LT cross-section of the multilayer ceramic capacitor 1 along the length direction L and the lamination direction T, at the center of the width direction W. The cross-sectional view of FIG. 5 illustrates a WT cross-section of the multilayer ceramic capacitor 1 along the width direction W and the lamination direction T, at the center of the length direction L.

The dimensions of the multilayer ceramic capacitor 1 may be, for example, between about 0.2 mm and about 1.2 mm inclusive in the length direction L, between about 0.1 mm and about 0.7 mm inclusive in the width direction W, and between and about 0.1 mm and about 0.7 mm inclusive in the lamination direction T. However, these dimensions are not limiting.

As illustrated in FIGS. 1 to 3, the pair of external electrodes 20 include a first external electrode 21 provided at one end of the base body 11 in the length direction L, and a second external electrode 22 provided at the other end of the base body 11 in the length direction L. Hereinafter, when there is no need to distinguish between the first external electrode 21 and the second external electrode 22 which have the same or substantially the same configuration, they may collectively be referred to simply as the external electrodes 20.

As illustrated in FIG. 4, both of the first external electrode 21 and the second external electrode 22 include a multilayer film including a sintered metal layer 20a and a plated layer 20b. The sintered metal layer 20a may be formed, for example, by firing a paste of metals such as Cu, Ni, Ag, Pd, Ag-Pd alloy, Au, etc. The plated layer 20b may include a Ni plated layer covered by a Sn plated layer, for example. The plated layer 20b may alternatively be, for example, a Cu plated layer or an Au plated layer. The external electrodes 20 may also solely include plated layers, or alternatively formed using electrically conductive resin paste.

As illustrated in FIGS. 2 and 5, the base body 11 includes a multilayer body 12 and a pair of lateral dielectric ceramic layers 15 covering both lateral surfaces of the multilayer body 12 in the width direction.

The multilayer body 12 includes a plurality of dielectric ceramic layers 13 and internal electrode layers 14 as internal electrodes, alternately stacked in the lamination direction T. The multilayer body 12 shares the same directions with the multilayer ceramic capacitor 1 and the base body 11, namely, the lamination direction T, the length direction L, and the width direction W.

The dielectric ceramic layers 13 and the lateral dielectric ceramic layers 15 are formed by firing, for example, a ceramic material primarily including barium titanate. The dielectric ceramic layers 13 and the lateral dielectric ceramic layers 15 may also be made using other high-dielectric ceramic materials (for example, materials primarily composed of CaTiO₃, SrTiO₃, CaZrO₃, etc.). The ceramic material for forming the dielectric ceramic layers 13 and the lateral dielectric ceramic layers 15 may include additives such as Si, Mg, Mn, Sn, Cu, rare earths, Ni, and Al, for the purpose of adjusting the composition, for example. The dielectric ceramic layers 13 and the lateral dielectric ceramic layers 15 may be made of the same or different materials, from among the ceramic materials as described above.

The internal electrode layers 14 are made of metal materials such as, for example, Ni, Cu, Ag, Pd, Ag-Pd alloy, Au, etc. Not limited to these metal materials, the internal electrode layers 14 may be made of other electrically conductive materials.

As illustrated in FIG. 4, one of the pair of neighboring internal electrode layers 14 sandwiching one dielectric ceramic layer 13 in the lamination direction T is electrically connected to the first external electrode 21, and the other is electrically connected to the second external electrode 22. As a result, a plurality of capacitor elements are electrically connected in parallel, between the first external electrode 21 and the second external electrode 22.

As illustrated in FIGS. 4 and 5, the dielectric ceramic layer 13 includes a plurality of first dielectric ceramic layers 13a sandwiched between the internal electrode layers 14, and a pair of second dielectric ceramic layers 13b provided at both ends in the lamination direction T and thicker than the first dielectric ceramic layers 13a.

As illustrated in FIGS. 4 and 5, the multilayer body 12 includes an inner layer portion 12A, in which the plurality of internal electrode layers 14 face each other across the first dielectric ceramic layers 13a, and a pair of outer layer portions 12B sandwiching the inner layer portion 12A in the lamination direction. In other words, the plurality of internal electrode layers 14 are alternately stacked across the first dielectric ceramic layers 13a in the inner layer portion 12A.

As illustrated in FIGS. 3 to 5, the multilayer body 12 includes a first main surface 17a1 and a second main surface 17a2 on opposite sides in the lamination direction T. As illustrated in FIGS. 2 and 5, the multilayer body 12 includes a first lateral surface 17b1 and a second lateral surface 17b2 on opposite sides in the width direction W. As illustrated in FIGS. 2 to 4, the multilayer body 12 includes a first end surface 17c1 and a second end surface 17c2 on opposite sides in the length direction L. The first external electrode 21 is provided on the first end surface 17c1, and the second external electrode 22 is provided on the second end surface 17c2.

As illustrated in FIGS. 2 and 5, the pair of lateral dielectric ceramic layers 15 are provided on the first lateral surface 17b1 and the second lateral surface 17b2, respectively, of the multilayer body 12. The pair of lateral dielectric ceramic layers 15 include a first lateral dielectric ceramic layer 15A covering the first lateral surface 17b1, and a second lateral dielectric ceramic layer 15B covering the second lateral surface 17b2. Hereinafter, when there is no need to distinguish between the first lateral dielectric ceramic layer 15A and the second lateral dielectric ceramic layer 15B which have the same or substantially the same configuration, they may be collectively referred to simply as the lateral dielectric ceramic layers 15.

The first lateral dielectric ceramic layer 15A includes a third lateral surface 15a that defines one lateral surface of the base body 11. The second lateral dielectric ceramic layer 15B includes a fourth lateral surface 15b that defines the other lateral surface of the base body 11. The third lateral surface 15a and the fourth lateral surface 15b are paired on opposite sides in the width direction W. The pair of surfaces on opposite sides in the lamination direction T of the base body 11 are the first main surface 17a1 and the second main surface 17a2 of the multilayer body 12. Therefore, in the following, the first main surface 17a1 and the second main surface 17a2 of the multilayer body 12 may also be referred to as the first main surface 17a1 and the second main surface 17a2 of the base body 11.

As described earlier, the first external electrode 21 is provided on the first end surface 17c1, and the second external electrode 22 is provided on the second end surface 17c2. The first external electrode 21 covers the entire or substantially the entire surface of the first end surface 17c1, and spans across the first main surface 17a1 and the second main surface 17a2 facing each other, and the first lateral surface 17b1 and the second lateral surface 17b2 facing each other.

As illustrated in FIGS. 2 to 4, the first external electrode 21 includes an end surface portion 21a covering the entire or substantially the entire surface of the first end surface 17c1, and a square-tube-shaped bent portion 21b, bending inward from the periphery of the end surface portion 21a along the length direction L, and covering a portion of the first main surface 17a1 and the second main surface 17a2 of the base body 11, and a portion of the third lateral surface 15a and the fourth lateral surface 15b of the base body 11. Similarly, the second external electrode 22 includes an end surface portion 22a covering the entire or substantially the entire surface of the second end surface 17c2, and a square-tube-shaped bent portion 22b, bending inward from the periphery of the end surface portion 22a along the length direction L, covering a portion of the first main surface 17a1 and the second main surface 17a2 of the base body 11, and a portion of the third lateral surface 15a and the fourth lateral surface 15b of the base body 11.

The central outer peripheral portion 30 is a portion exposed between the pair of external electrodes 20. The central outer peripheral portion 30 of the example embodiment covers the outer peripheral surface of the base body 11 between the pair of external electrodes 20, i.e., the four surfaces including the first main surface 17a1, the second main surface 17a2, the third lateral surface 15a, and the fourth lateral surface 15b between the pair of external electrodes 20. In other words, the central outer peripheral portion 30 is provided over the entire outer periphery of the component body 10.

The thickness of the central outer peripheral portion 30, which covers the first main surface 17a1, the second main surface 17a2, the third lateral surface 15a, and the fourth lateral surface 15b of the base body 11 (in other words, the dimension from the surfaces of the first main surface 17a1, the second main surface 17a2, the third lateral surface 15a, and the fourth lateral surface 15b to the surface of the central outer peripheral portion 30), is greater than the film thickness of the bent portions 21b and 22b of the external electrodes 20. Thus, the central outer peripheral portion 30 protrudes outward beyond the bent portions 21b and 22b both in the lamination direction T and the width direction W.

The central outer peripheral portion 30 includes a first protrusion 31 covering the first main surface 17a1, a second protrusion 32 covering the second main surface 17a2, a third protrusion 33 covering the third lateral surface 15a, and a fourth protrusion 34 covering the fourth lateral surface 15b, between the pair of external electrodes 20. The first protrusion 31 and the second protrusion 32 protrude outward beyond the surfaces of the bent portions 21b and 22b of the external electrodes 20, in the lamination direction T orthogonal or substantially orthogonal to the length direction L. The third protrusion 33 and the fourth protrusion 34 protrude outward beyond the surfaces of the bent portions 21b and 22b of the external electrodes 20, in the width direction W orthogonal or substantially orthogonal to the length direction L. The lamination direction T and the width direction W each are one direction orthogonal or substantially orthogonal to the length direction L. The first protrusion 31, the second protrusion 32, the third protrusion 33, and the fourth protrusion 34 of the central outer peripheral portion 30 are examples of protrusions that extend outward beyond the external electrodes 20 in one direction orthogonal or substantially orthogonal to the length direction L.

As illustrated in FIG. 3, the first protrusion 31 and the second protrusion 32 protrude outward in the lamination direction T by the dimension H from the surfaces of the bent portion 21b of the first external electrode 21 and the bent portion 22b of the second external electrode 22, respectively. As illustrated in FIG. 2, the third protrusion 33 and the fourth protrusion 34 protrude outward in the width direction W by the dimension H from the surfaces of the bent portion 21b of the first external electrode 21 and the bent portion 22b of the second external electrode 22, respectively. Each dimension H is, for example, preferably at least about 15 μm.

The surface of the first protrusion 31 is flat and parallel or substantially parallel to the first main surface 17a1. The surface of the second protrusion 32 is flat and parallel or substantially parallel to the second main surface 17a2. The surface of the third protrusion 33 is flat and parallel or substantially parallel to the third lateral surface 15a. The surface of the fourth protrusion 34 is flat and parallel or substantially parallel to the fourth lateral surface 15b.

The central outer peripheral portion 30 can be made, from at least one of the materials such as, for example, ceramic and resin, on the surface of the base body 11. When the central outer peripheral portion 30 is made of ceramic, the ceramic material may be the same as the dielectric ceramic layers 13 or the lateral dielectric ceramic layers 15. When the central outer peripheral portion 30 is made of resin, synthetic resins such as, for example, epoxy resin or acrylic resin may be used.

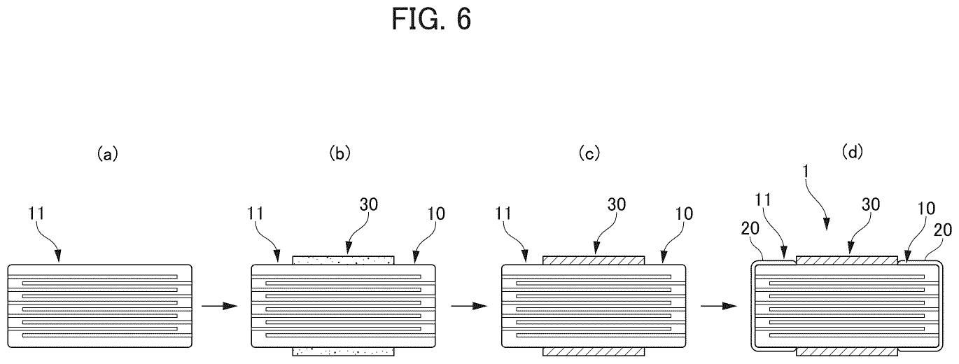

Hereinafter, an example of a method of manufacturing the multilayer ceramic capacitor 1 according to the present example embodiment is briefly described with reference to FIG. 6. FIG. 6 schematically illustrates the steps in the example method of manufacturing the multilayer ceramic capacitor 1. In this case, the central outer peripheral portion 30 is formed from ceramic.

Initially, as illustrated in FIG. 6 (a), the base body 11 is produced. The base body 11 is formed by, for example, stacking ceramic material such as ceramic green sheets for the dielectric ceramic layers 13 and electrically conductive material such as electrically conductive paste for the internal electrode layers 14 to form the multilayer body 12, and then attaching ceramic material such as ceramic green sheets for the lateral dielectric ceramic layers 15 to the first lateral surface 17b1 and the second lateral surface 17b2 of the multilayer body 12. Next, as illustrated in FIG. 6(b), ceramic material such as a ceramic green sheet for the central outer peripheral portion 30 is attached to the base body 11. As a result, a pre-fired component body 10 is formed. Subsequently, the pre-fired component body 10 is fired, resulting in the fired component body 10 as illustrated in FIG. 6(c). Finally, as illustrated in FIG. 6(d), the external electrodes 20 are formed on both end portions of the base body 11 in the length direction L. When the central outer peripheral portion 30 is formed from the same ceramic material as the multilayer body 12 and the lateral dielectric ceramic layers 15, the central outer peripheral portion 30 is integrated with the base body 11.

When the central outer peripheral portion 30 is formed using the resin, after forming the external electrodes 20, the central outer peripheral portion 30 can be formed by, for example, applying liquid resin material by injecting to the outer peripheral surface of the base body 11 between the external electrodes 20 using the appropriate tools, and then curing the applied resin material.

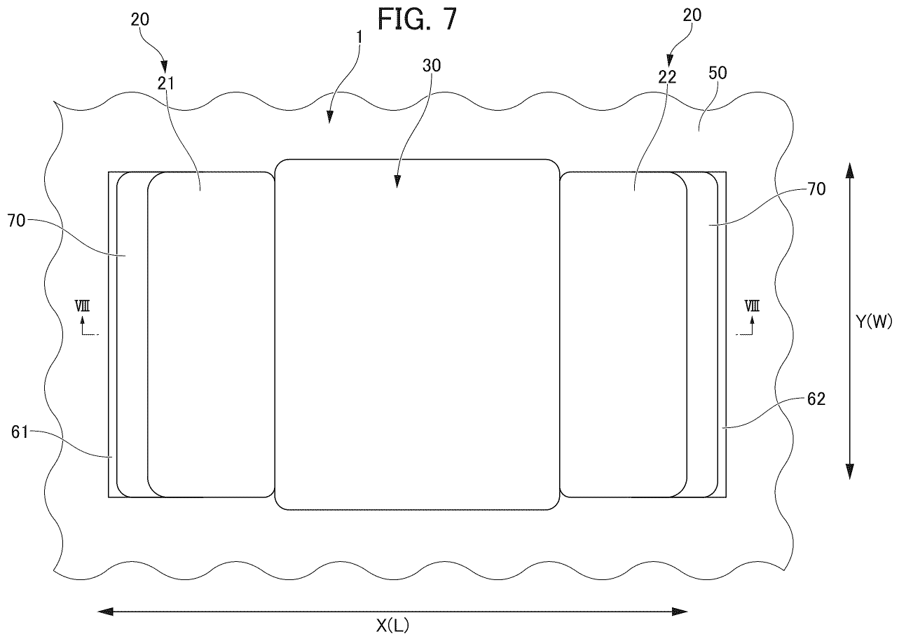

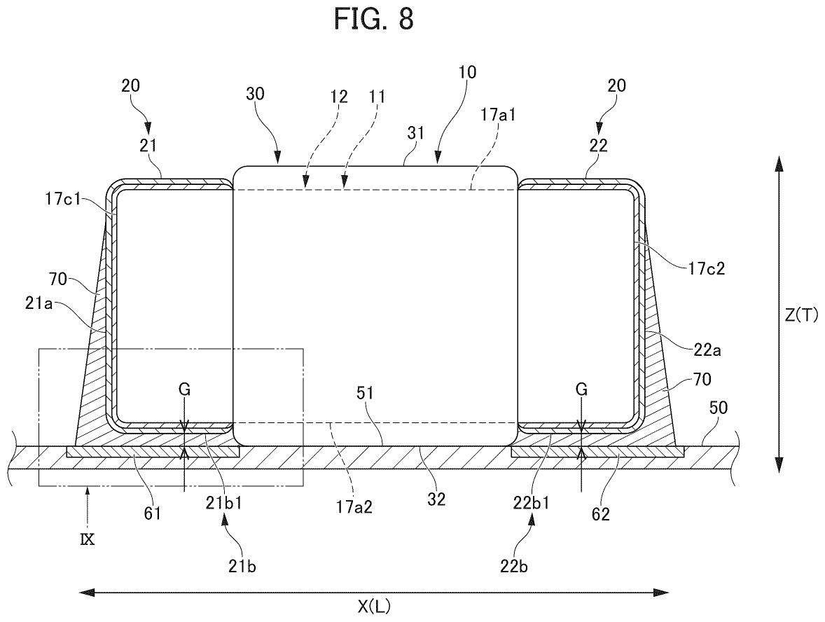

Next, a mounting structure for a multilayer ceramic capacitor 1 according to an example embodiment of the present invention is described. FIG. 7 is a plan view illustrating the mounting structure according to the present example embodiment. FIG. 8 is a cross-sectional view taken along the line VIII-VIII in FIG. 7. The mounting structure according to the present example embodiment is the multilayer ceramic capacitor 1 mounted on a board 50.

As illustrated in FIGS. 7 and 8, in the mounting structure according to the present example embodiment, the pair of external electrodes 20 of the multilayer ceramic capacitor 1 are connected to a first land 61 and a second land 62, respectively, as the first and second lands being spaced apart on the surface of the board 50.

The board 50 is, for example, made of a sheet of insulating material such as, for example, resin, glass, glass epoxy, paper phenol, ceramics, etc. Areas that require insulation are covered with a resist film on the surface of the board 50. The multilayer ceramic capacitor 1 is mounted on the board 50, in which the length direction L is parallel or substantially parallel to the X direction as illustrated in FIGS. 7 and 8, and the width direction W is parallel or substantially parallel to the Y direction orthogonal or substantially orthogonal to the X direction. In FIG. 7, both the X and Y directions are the planar directions along the surface of the board 50. FIG. 7 also indicates the length direction L and the width direction W of the multilayer ceramic capacitor 1. FIG. 8 also indicates the length direction L and the lamination direction T of the multilayer ceramic capacitor 1. The Z direction in FIG. 8 is the vertical direction orthogonal or substantially orthogonal to both the X and Y directions.

The board 50 may be made from materials based on, for example, glass or paper fibers. The fibers of the base materials may include fibers oriented in a particular direction. In the present example embodiment, when the board 50 include fibers oriented in a particular direction, the multilayer ceramic capacitor 1 is preferably mounted to have the fiber orientation extending in the X direction as illustrated in FIGS. 7 and 8. In other words, the multilayer ceramic capacitor 1 is preferably mounted such that the direction of the pair of external electrodes 20 spaced apart from each other are aligned parallel or substantially parallel to the fiber orientation of the board 50. Being “parallel” indicates that the two directions form an angle of, for example, about −5 degrees or more and less than about +5 degrees.

The first land 61 and the second land 62 are spaced apart from each other in the X direction. Both of the first land 61 and the second land 62 are rectangular or substantially rectangular and have the same or substantially the same dimension in a plan view. A spacing portion 51 covered with a resist film is provided between the first land 61 and the second land 62. The first land 61 and the second land 62, sandwiching the spacing portion 51, are juxtaposed to be spaced apart in the X direction, and arranged at the same or substantially the same position in the Y direction.

In the multilayer ceramic capacitor 1, the bent portion 21b of the first external electrode 21 is connected to the first land 61, and the bent portion 22b of the second external electrode 22 is connected to the second land 62. In the present example embodiment, as illustrated in FIG. 8, the first connecting bent portion 21b1 of the first bent portion 21b, which covers the second main surface 17a2 of the base body 11, is connected to the first land 61, and the second connecting bent portion 22b1 of the second bent portion 22b, which covers the second main surface 17a2 of the base body 11, is connected to the second land 62. The points of connection of the first external electrode 21 and the second external electrode 22 to the board 50 may be the portions of the bent portion 21b and the bent portion 22b which cover the first main surface 17a1. Additionally, the points of connection of the first external electrode 21 and the second external electrode 22 to the board 50 may be the portions of the bent portion 21b and the bent portion 22b which cover the first lateral surface 17b1 or the second lateral surface 17b2.

Each of the first land 61 and the second land 62 is connected to wiring (not illustrated) formed on the board 50. The first land 61 and the second land 62 are provided at the ends of the wiring, respectively. In other words, the wiring is discontinuous across the spacing portion 51, and electrical conduction is provided when the multilayer ceramic capacitor 1 is connected to the first land 61 and the second land 62.

The first land 61, the second land 62, and the wiring are preferably made of a highly electrically conductive metal, such as Cu, for example, deposited on the surface of the board 50. Other suitable highly electrically conductive metals may include, for example, Ag and Au.

As illustrated in FIG. 8, in the present example embodiment of the mounting structure for the multilayer ceramic capacitor 1, the second protrusion 32 of the central outer peripheral portion 30 is in contact with the surface of the spacing portion 51 of the board 50. The second protrusion 32 covers the second main surface 17a2 of the base body 11. The surface of the second protrusion 32 in contact with the board 50 is flat and parallel or substantially parallel to the second main surface 17a2. This allows the multilayer ceramic capacitor 1 to be set in a stable posture on the board 50. The first connecting bent portion 21b1 of the first external electrode 21 faces the first land 61 of the board 50, and the second connecting bent portion 22b1 of the second external electrode 22 faces the second land 62 of the board 50.

As illustrated in FIG. 8, the second protrusion 32 protrudes downward (outward in the lamination direction T of the multilayer ceramic capacitor 1) beyond the first connecting bent portion 21b1 and the second connecting bent portion 22b1 on both sides in the length direction L. Therefore, in a state where the second protrusion 32 is set in the spacing portion 51, the multilayer ceramic capacitor 1 includes a gap G between the first connecting bent portion 21b1 and the first land 61, and a gap G between the second connecting bent portion 22b1 and the second land 62. In other words, the first external electrode 21 and the second external electrode 22 are suspended above the surface of the board 50. The gap G is equivalent to the dimension H of the amount of protrusion from the first bent portion 21b and the second bent portion 22b of the central outer peripheral portion 30 as illustrated in FIG. 3. The gap G is, for example, preferably at least about 15 μm.

The multilayer ceramic capacitor 1 is mounted on the board 50 in the above-described state of arrangement. The mounting on the board 50 includes soldering the first external electrode 21 to the first land 61, and soldering the second external electrode 22 to the second land 62. As illustrated in FIGS. 7 and 8, the first external electrode 21 and the first land 61, as well as the second external electrode 22 and the second land 62, are electrically connected through the solder 70.

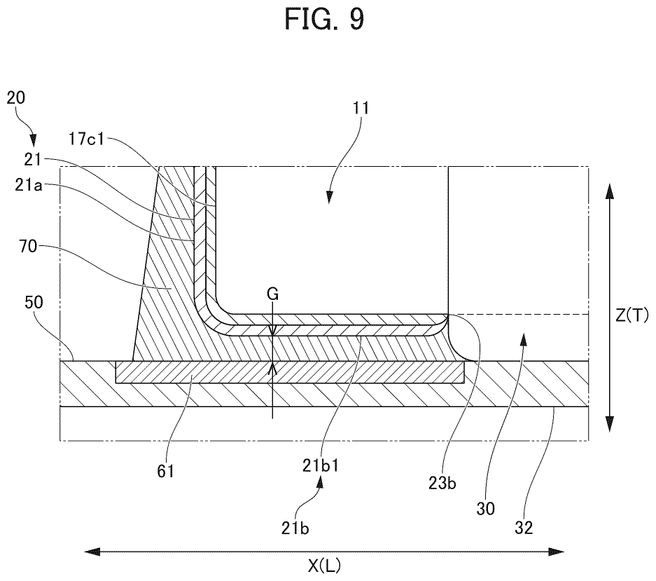

FIG. 9 is an enlarged view of the section IX illustrated in FIG. 8. As illustrated in FIG. 9, the solder 70 fills the gap G between the first connecting bent portion 21b1 of the first external electrode 21 and the first land 61, extending from the gap G to the end surface portion 21a of the first external electrode 21.

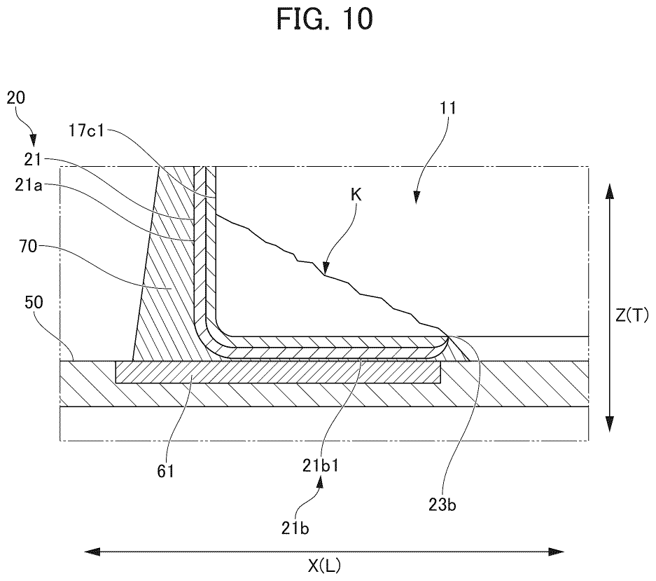

FIG. 10 is a diagram illustrating a conventional multilayer ceramic capacitor mounted on the board 50, corresponding FIG. 9. In FIG. 10, the elements corresponding to those of the example embodiment are assigned with the same reference numbers. As illustrated in FIG. 10, in the conventional multilayer ceramic capacitor, the first external electrode 21 protrudes below the base body 11 of the component body 10, and thus the first external electrode 21 contacts the first land 61. Therefore, when the multilayer ceramic capacitor is set on the board 50, there is no gap G between the first external electrode 21 and the first land 61, unlike the present example embodiment. As a result, during soldering, it is difficult for the solder 70 to sufficiently penetrate between the first external electrode 21 and the first land 61, and it is challenging to ensure an adequate amount of the solder 70 between the first external electrode 21 and the first land 61. If the amount of the solder 70 in this portion is insufficient, when the board 50 bends under the stress to curve the multilayer ceramic capacitor along the length direction L, the stress is likely to concentrate at the edge 23b of the bent portion 21b, potentially causing cracks K to start occurring from the edge 23b in the base body 11.

Conversely, in the present example embodiment of the multilayer ceramic capacitor 1 and the mounting structure, since the gap G exists between the first external electrode 21 and the first land 61, it is possible to cause a sufficient amount of the solder 70 to fill between the first external electrode 21 and the first land 61 in the soldered state. As long as the gap G is, for example, at least about 15 μm, an adequate amount of the solder 70 can be ensured between the first external electrode 21 and the first land 61. Therefore, when the board 50 bends as described, stress is less likely to concentrate at the edge 23b of the bent portion 21b, thus reducing or preventing cracks from occurring from the edge 23b in the base body 11.

Among the pair of external electrodes 20, the second external electrode 22 is the same as or similar to the first external electrode 21 illustrated in FIG. 9. As illustrated in FIG. 8, and since the gap G also exists between the second connecting bent portion 22b1 of the second external electrode 22 and the second land 62, the solder 70 is filled into this gap G as well. Thus, cracks in the base body 11 can be reduced or prevented in the second external electrode 22 as well.

According to the example embodiment described above, the multilayer ceramic capacitor 1 can achieve the following advantageous effects.

The multilayer ceramic capacitor 1 of the present example embodiment includes the component body 10 with a length in the length direction L, and the pair of external electrodes 20 provided at both ends of the component body 10 in the length direction L. The component body 10 includes the central outer peripheral portion 30 protruding outwardly beyond the pair of external electrodes 20 in one direction orthogonal or substantially orthogonal to the length direction L, at least in a portion of an area exposed between the pair of external electrodes 20.

Upon mounting the multilayer ceramic capacitor 1 of the present example embodiment on the board 50, when the multilayer ceramic capacitor 1 is set in the predetermined mounting position on the board 50, the central outer peripheral portion 30 contacts the surface of the board 50, creating the gap G between the external electrodes 20 and the first and second lands 61 and 62. When the external electrodes 20 are soldered to the first and second lands 61 and 62, the solder 70 fills this gap G. This allows a sufficient amount of the solder 70 to fill the space between the external electrodes 20 and the first and second lands 61 and 62. Thus, when the board 50 bends, the stress is less likely to be transmitted to the base body 11, thus reducing or preventing cracks in the base body 11.

The central outer peripheral portion 30 of the multilayer ceramic capacitor 1 of the present example embodiment preferably protrudes, for example, at least about 15 μm outward from the external electrodes 20 in the one direction.

This allows the gap G between the external electrodes 20 and the first and second lands 61 and 62 to be at least about 15 μm, enabling a sufficient amount of the solder 70 to fill the gap G. As a result, the transmission of stress from the board 50 to the base body 11 via the solder 70 is effectively blocked, thus reducing or preventing cracks in the base body 11.

In the present example embodiment of the multilayer ceramic capacitor 1, the central outer peripheral portion 30 is provided around the entire or substantially the entire outer periphery of the component body 10.

This ensures that no matter which portion of the central outer peripheral portion 30 is set facing the board 50, a gap G will exist between the external electrodes 20 and the first and second lands 61 and 62. Therefore, there is no need to select a particular orientation to set the multilayer ceramic capacitor 1 on the board 50, thus simplifying the mounting process.

In the present example embodiment of the multilayer ceramic capacitor 1, the component body 10 includes the base body 11 including the internal electrode layers 14, the central outer peripheral portion 30 is provided on the surface of the base body 11, and the central outer peripheral portion 30 includes at least one of ceramic or resin.

As a result, the central outer peripheral portion 30 can be easily provided in the desired location and shape. In particular, by making the central outer peripheral portion 30 from the same ceramic material as the dielectric ceramic layers 13, since it is possible to simultaneous fire the base body 11 and the central outer peripheral portion 30, the manufacturing efficiency improves.

In the mounting structure for the multilayer ceramic capacitor 1 according to the example embodiment, the pair of external electrodes 20 are connected to the first land 61 and the second land 62, respectively, spaced apart on the surface of the board 50. The multilayer ceramic capacitor 1 includes the component body 10 and the pair of external electrodes 20 provided on the component body 10. The component body 10 contacts the board 50, and the gap G exists between each of the pair of external electrodes 20 and the board 50.

When the external electrodes 20 are soldered to the first land 61 and the second land 62, the solder 70 fills the gap G. This allows for a sufficient amount of the solder 70 to be filled between the external electrodes 20 and the first and second lands 61 and 62. Therefore, if the board 50 bends, the resulting stress is less likely to be transmitted to the base body 11, thus reducing or preventing cracks in the base body 11.

In the example embodiment of the mounting structure, the gap G between each of the external electrodes 20 and the board 50 is, for example, preferably at least about 15 μm.

This enables a sufficient amount of the solder 70 to fill the gap G. As a result, the transmission of stress from the board 50 to the base body 11 via the solder 70 is effectively blocked, thus reducing or preventing cracks in the base body 11.

In the present example embodiment of the mounting structure, the board 50 includes the fiber orientation extending in one direction, and the multilayer ceramic capacitor 1 is preferably arranged such that the direction in which the pair of external electrodes 20 are spaced apart from each other is aligned parallel or substantially parallel to the fiber orientation. In the present example embodiment, the direction of the pair of external electrodes 20 are spaced apart from each other is the length direction L.

From a rigidity standpoint, the multilayer ceramic capacitor 1 is more susceptible to stress due to bending in the length direction L, than in the width direction W. However, the multilayer ceramic capacitor 1 is arranged on the board 50 such that the length direction L aligns with the fiber direction of the board 50, such that the rigidity provided by the fibers of the board 50 helps reduce the stress acting on the multilayer ceramic capacitor 1, as compared to the arrangement in a direction intersecting the fiber direction. This can improve the effectiveness in reducing or preventing cracks.

The present invention is not limited to the example embodiments described above and includes modifications or improvements thereof.

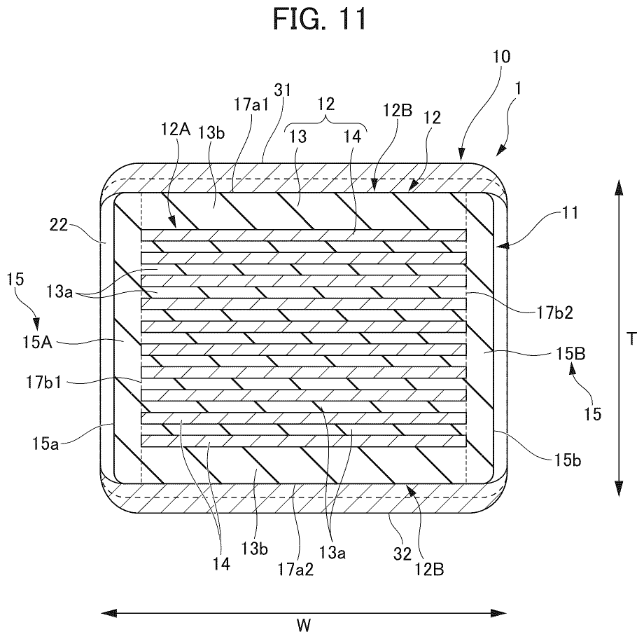

For example, the protrusions that keep the external electrodes 20 suspended above the surface of the board 50 do not necessarily need to cover the entire or substantially the entire periphery of the component body 10. As illustrated in FIG. 11, only two protrusions may be sufficient, i.e., the first protrusion 31 provided on the first main surface 17a1 of the base body 11, and the second protrusion 32 provided on the second main surface 17a2 of the base body 11. In this case, the multilayer ceramic capacitor 1 is set on the board 50, in which either the first protrusion 31 or the second protrusion 32 contacts the surface of the board 50. Furthermore, only one of the first protrusion 31 and the second protrusion 32 may be provided.

Only two protrusions may be provided, i.e., the third protrusion 33 provided on the third lateral surface 15a of the base body 11, and the fourth protrusion 34 provided on the fourth lateral surface 15b of the base body 11. In this case, the multilayer ceramic capacitor 1 is set on the board 50, in which either the third protrusion 33 or the fourth protrusion 34 contacts the surface of the board 50. Furthermore, only one of the third protrusion 33 and the fourth protrusion 34 may be provided.

The multilayer ceramic capacitor 1 described above in the example embodiment is one example of electronic components, and the present invention is not limited to this type of electronic component, and rather is applicable to other two-terminal electronic components such as thermistors and inductors, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component, comprising:
a component body with a length in a length direction; and
a pair of external electrodes at both ends of the component body, respectively, in the length direction; wherein
the component body includes a protrusion protruding outwardly beyond the pair of external electrodes in one direction orthogonal or substantially orthogonal to the length direction, in at least a portion of an area exposed between the pair of external electrodes.

2. The electronic component according to claim 1, wherein the protrusion protrudes outwardly from the external electrodes by at least about 15 μm in the one direction.

3. The electronic component according to claim 1, wherein the protrusion is provided around an entire or substantially an entire outer periphery of the component body.

4. The electronic component according to claim 1, wherein
the component body includes a base body including an internal electrode;
the protrusion is provided on a surface of the base body; and
the protrusion includes at least one of ceramic and resin.

5. The electronic component according to claim 1, wherein dimensions of the electronic component are between about 0.2 mm and about 1.2 mm inclusive in the length direction, between about 0.1 mm and about 0.7 mm inclusive in a width direction, and between and about 0.1 mm and about 0.7 mm inclusive in a lamination direction.

6. The electronic component according to claim 1, wherein each of the pair of external electrodes includes a multilayer film including a sintered metal layer and a plated layer.

7. The electronic component according to claim 6, wherein the sintered metal layer includes Cu, Ni, Ag, Pd, an Ag-Pd alloy, or Au.

8. The electronic component according to claim 6, wherein the plated layer includes a Ni plated layer and a Sn plated layer covering the Ni plated layer.

9. The electronic component according to claim 1, wherein each of the pair of external electrodes extends from the respective end surface of the component body to lateral side surfaces and main side surfaces of the component body.

10. The electronic component according to claim 1, wherein the component body includes a plurality of dielectric ceramic layers and a plurality of internal electrode layers alternatively stacked in a lamination direction.

11. The electronic component according to claim 10, wherein each of the plurality of dielectric ceramic layers includes barium titanate.

12. A mounting structure for an electronic component comprising:
a pair of external electrodes respectively connected to a pair of lands spaced apart on a surface of a board; wherein
the electronic component includes a component body and the pair of external electrodes provided on the component body; and
the component body is in contact with the board, and a gap is provided between each of the pair of external electrodes and the board.

13. The mounting structure according to claim 12, wherein the gap is at least about 15 μm.

14. The mounting structure according to claim 12, wherein
the board includes a fiber orientation extending in one direction; and
the electronic component is arranged such that a direction in which the pair of external electrodes are spaced apart from each other is parallel or substantially parallel to the fiber orientation.

15. The mounting structure according to claim 12, wherein dimensions of the electronic component are between about 0.2 mm and about 1.2 mm inclusive in the length direction, between about 0.1 mm and about 0.7 mm inclusive in a width direction, and between and about 0.1 mm and about 0.7 mm inclusive in a lamination direction.

16. The mounting structure according to claim 12, wherein each of the pair of external electrodes includes a multilayer film including a sintered metal layer and a plated layer.

17. The mounting structure according to claim 16, wherein the sintered metal layer includes Cu, Ni, Ag, Pd, an Ag-Pd alloy, or Au.

18. The mounting structure according to claim 16, wherein the plated layer includes a Ni plated layer and a Sn plated layer covering the Ni plated layer.

19. The mounting structure according to claim 12, wherein each of the pair of external electrodes extends from the respective end surface of the component body to lateral side surface and main side surfaces of the component body.

20. The mounting structure according to claim 12, wherein the component body includes a plurality of dielectric ceramic layers and a plurality of internal electrode layers alternatively stacked in a lamination direction.
